(19) United States
(12) Patent Application Publication
(10) Pub. No.: US 2025/0379055 A1
(43) Pub. Date: Dec. 11, 2025

(54) COMBINATORIAL TREATMENTS FOR EUV PATTERNED LAYERS

(71) Applicant: Applied Materials, Inc., Santa Clara, CA (US)

(72) Inventors: RUDY WOJTECKI, East Garrison, CA (US); ZHIYU HUANG, Sunnyvale, CA (US); MADHUR SACHAN, Belmont, CA (US); SWASTI BHATIA, Gloucester, MA (US); BEKELE WORKU, San Jose, CA (US); JOHN HAUTALA, Beverly, MA (US); SHASHANK SHARMA, Sunnyvale, CA (US); Kai Ng, Santa Clara, CA (US); Nila Mohan Thazhe Mecheri, Sunnyvale, CA (US)

(21) Appl. No.: 19/213,876

(22) Filed: May 20, 2025

Related U.S. Application Data
(60) Provisional application No. 63/658,369, filed on Jun. 10, 2024.

(51) Int. Cl. H01L 21/033; G03F 7/00; G03F 7/09; G03F 7/42

(52) U.S. Cl. CPC H01L 21/0337; G03F 7/093; G03F 7/42; G03F 7/70033

(57) ABSTRACT

Embodiments described herein relate to a method for lithographic patterning, that includes depositing a patterning stack over a substrate, where the patterning stack includes a responsive layer and a resist layer, and forming a pattern in the resist layer. In an embodiment, the method further includes transferring the pattern into the responsive layer, where the responsive layer has a first line width roughness (LWR), and treating the responsive layer, where the treated responsive layer has a second LWR that is smaller than the first LWR.

### CROSS-REFERENCE TO RELATED APPLICATIONS

This application claims the benefit of U.S. Provisional Application No. 63/658,369, filed on Jun. 10, 2024, the entire contents of which are hereby incorporated by reference herein.

### BACKGROUND

### 1) Field

Embodiments relate to the field of semiconductor manufacturing and, in particular, apparatuses and methods for using a responsive layer in an extreme ultraviolet (EUV) patterning stack for improved line width roughness (LWR) and line edge roughness (LER).

### 2) Description of Related Art

Semiconductor devices are continuously scaling to smaller feature sizes. Improvements in lithography systems are needed in order to keep up with shrinking features. For example, extreme ultraviolet (EUV) lithography has been used in order to enable the printing of smaller features. Unfortunately, EUV resists suffer from poor absorption of the EUV radiation. That is, the chemical structure within the EUV resist does not easily react in the presence of the EUV radiation in order to generate the necessary solubility switch. Accordingly, larger doses of EUV radiation are needed in order to obtain the desired contrast in the resist layer.

Increasing the dose causes an increase in the exposure time. This reduces the throughput of the system and increases the cost of EUV lithography. Some tradeoffs can be made in order to reduce the necessary dose. For example, a lower dose of EUV radiation may be used at the expense of line edge roughness (LER) and/or line width roughness (LWR). High LER and LWR can negatively impact pattern transfer, and may not be desirable for all patterning processes.

### SUMMARY

Embodiments described herein relate to a method for lithographic patterning, that includes depositing a patterning stack over a substrate, where the patterning stack includes a responsive layer and a resist layer, and forming a pattern in the resist layer. In an embodiment, the method further includes transferring the pattern into the responsive layer, where the responsive layer has a first line width roughness (LWR), and treating the responsive layer, where the treated responsive layer has a second LWR that is smaller than the first LWR.

Embodiments described herein relate to a method for lithographic patterning that includes depositing a patterning stack on a substrate, where the patterning stack includes a carbon layer, a hardmask layer, a responsive layer, and a resist layer over the responsive layer. In an embodiment, the method further includes forming a pattern in the resist layer, and transferring the pattern into the responsive layer. In an embodiment, the method further includes reflowing the responsive layer through application of a stimulus, where a line edge roughness (LER) of the responsive layer is reduced by the reflowing.

Embodiments described herein relate to a lithography patterning stack that includes a carbon containing layer, a hardmask layer over the carbon containing layer, and a responsive layer over the hardmask layer. In an embodiment, the responsive layer includes a material that is configured to reflow in the presence of a stimulus that includes one or more of a rapid thermal anneal, ion implantation, or a plasma treatment. In an embodiment, a resist layer is over the responsive layer.

### BRIEF DESCRIPTION OF THE DRAWINGS

FIG. 1 is a cross-sectional illustration of a substrate with a patterned resist layer that includes poor line edge roughness (LER) and poor line width roughness (LWR), in accordance with an embodiment.

FIG. 2 is a graph of exposure dose versus LER and illustrates that higher exposure doses result in improved LER, in accordance with an embodiment.

FIG. 3A is a cross-sectional illustration of a substrate with a patterning stack that comprises a responsive layer under a resist, in accordance with an embodiment.

FIG. 3B is a cross-sectional illustration of a substrate with a patterning stack that comprises a responsive layer under a resist with an underlayer between the responsive layer and the resist, in accordance with an embodiment.

FIGS. 4A-4E are cross-sectional illustrations depicting a process for patterning a substrate with a patterning stack that comprises a modifiable responsive layer, in accordance with an embodiment.

FIGS. 5A-5C are cross-sectional illustrations depicting a process for patterning a substrate with a patterning stack that comprises a modifiable responsive layer, in accordance with an additional embodiment.

FIG. 6 is a diagram of chemistries that may be used to form a disulfide layer that can be used for the responsive layer, in accordance with an embodiment.

FIG. 7 is a process flow diagram of a process for patterning a substrate with a patterning stack that comprises a modifiable responsive layer that exhibits a decrease in LER when exposed to a stimulus treatment, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include apparatuses and methods for using a responsive layer in an extreme ultraviolet (EUV) patterning stack for improved line width roughness (LWR) and line edge roughness (LER). In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

In EUV lithography, a resist that is chemically reactive to EUV radiation is deposited over a substrate. The EUV resist may include a metal-oxide (e.g., tin-oxide) material, or a chemically amplified resist (CAR) system. Once deposited, the resist is selectively exposed with EUV radiation through the use of a mask and/or reticle. The EUV radiation initiates a chemical reaction within the resist. The chemical reaction may result in a solubility change of the exposed regions of the resist. The exposed resist may sometimes be considered as having a latent image of the desired pattern. After exposure, a developing process may be used to selectively remove the exposed regions relative to the unexposed regions, or the unexposed regions may be selectively removed relative to the exposed regions (depending on if the resist is a positive tone resist or a negative tone resist).

The pattern formed within the resist may then be transferred into an underlying patterning stack. However, the surface features of the pattern in the resist may be transferred into underlying layers as well. Accordingly, if the resist is not patterned with straight sidewalls (e.g., a low LER or a low LWR), the undesirable topography of the sidewalls will be transferred into the underlying layers.

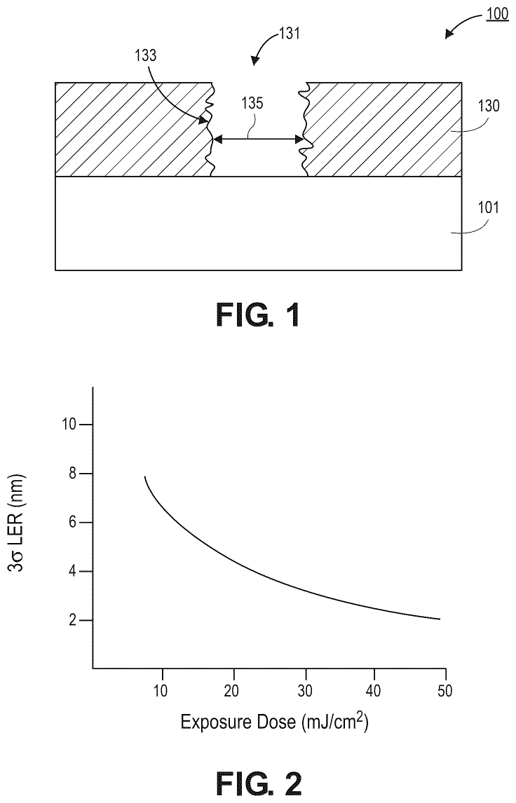

Typically, EUV lithography systems suffer from low absorption of the EUV radiation in the resist. A consequence of the low absorption is that the edges of the patterned resist have high LER and high LWR. An example of a device 100 with a patterned resist layer 130 is shown in FIG. 1. FIG. 1 is a cross-sectional illustration of a substrate 101 with a resist layer 130 over the substrate 101. The substrate 101 may be any type of substrate (e.g., silicon wafer, or the like). While the resist layer 130 is shown as being directly on the substrate 101, other embodiments may include one or more intervening layers between the substrate 101 and the resist layer 130. For example, a patterning stack similar to any of the patterning stacks described in greater detail below may be provided between the substrate 101 and the resist layer 130.

In an embodiment, the resist layer 130 may be an EUV resist material, such as a metal-oxide based material or a CAR. While an EUV resist is described in detail herein, it is to be appreciated that other resist materials and lithography regimes may also suffer from similar absorption issues. That is, the term “resist layer” or “resist” may comprise any type of resist material, such as those compatible with EUV radiation, deep ultraviolet (DUV) radiation, or any other wavelength or wavelengths of electromagnetic radiation suitable for photolithography processes. In an embodiment, the resist layer 130 may have been exposed and developed with a process similar to the process described in greater detail above. As such, an opening 131 (sometimes also referred to as a trench, a hole, or a pattern) may pass through a thickness of the resist layer 130. The opening 131 may have sidewalls 133. As shown, the sidewalls 133 have a non-linear and irregular profile. That is, the LER of the sidewalls 133 is relatively high. Similarly the LWR 135 (i.e., the variation of the width of the opening 131 through the thickness of the resist layer 130) is high. These traits can lead to poor pattern transfer into the underlying substrate 101.

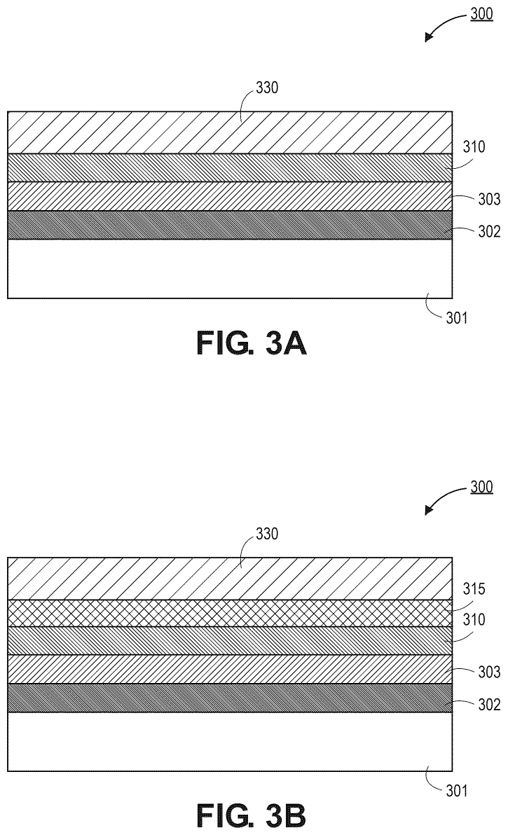

The LER and/or LWR can be improved by increasing the dose of the exposure during the lithographic exposure process. However, increasing the dose requires a longer exposure duration. This can lead to a lower throughput and/or a higher cost of the EUV lithography process. FIG. 2 is a graph that shows the general relationship between the exposure dose (x-axis) and the LER (y-axis). Lower LER is associated with improved patterning performance. As shown, increasing the dose can provide an improvement (i.e., decrease) in the LER. The improvement can be significant in some embodiments. For example, a LER of around 8 nm can be decreased to around 2 nm when the dose is significantly increased.

Ideally, a reduction in LER and LWR is obtained without needing to increase the dose. This allows for improved throughput without sacrificing patterning performance. Previous research has been focused on improving the chemistry of the resist layer in order to provide such results. However, embodiments disclosed herein use a modifiable responsive layer below the resist in order to improve the LER and LWR. The responsive layer is formed from a material that is capable of “reflow” in response to a stimulus. As such, the responsive layer may be patterned and have a first LER/LWR similar to that of the resist layer. A stimulus (e.g., thermal, electromagnetic radiation, or chemical) is then applied to the responsive layer to initiate the reflow in order to produce a second LER/LWR that is smaller than the first LER/LWR.

In some embodiments, the stimulus may include a plasma treatment, such as a plasma ignited from a gas comprising one or more of HBr, CH₄, or O₂. Such plasma treatments may result in degradation of the organic compounds of the responsive layer through chain scission. This locally lowers the molecular weight of the responsive layer at the surface. The lower molecular weight enables a skin depth reflow that allows the sidewall surfaces of the pattern in the responsive layer to reflow in order to minimize LER and/or LWR.

In other embodiments, the stimulus may include a rapid thermal anneal, such as one comprising a laser annealing treatment. The laser annealing treatment may allow for rapid heating of the responsive layer at specific locations. The rapid heating provides the necessary energy to allow for reflow of the sidewall surfaces of the responsive layer in order to minimize LER and/or LWR. Further, the use of laser annealing provides rapid cooling after the reflow of the surface. This prevents the bulk of the responsive layer from reflowing, which may otherwise result in the merging of patterned features, as may be the case if the substrate were heated on a heat plate or in a heated chamber.

In yet another embodiment, the stimulus may comprise an ion implantation treatment. Ions with a relatively high molecular weight (e.g., xenon or argon) or any other suitable ion (e.g., neon, helium, nitrogen (N₂)) may be used for the ion implantation. The higher molecular weight may limit the penetration depth of the implanted ion into the responsive layer. Accordingly, a high amount of energy is locally provided to the sidewall surfaces of the responsive layer in order to provide localized surface reflow. The surface reflow can minimize LER and/or LWR.

As used herein “reflow” may refer to several different processes. In one embodiment, reflow may refer to bringing a material above a glass transition temperature of the material or a melting point of the material. In this state, the material can flow (similar to a fluid). In other embodiments, reflow may refer to a chemical process that includes cross-linking and/or rearrangement of chemical bonds within the material. Generally, reflowing the responsive layer may allow for changes to the topography of the surfaces of the material in order to decrease the surface energy of the responsive layer.

In an embodiment, the responsive layer may also provide functionality of an underlayer. For example, the responsive layer may be a source of secondary electron generation and/or the generation of radicals or other chemical species that diffuse into the resist layer during exposure. The secondary electrons and chemical species may improve the patterning performance of the resist layer. In other embodiments, the responsive layer may be a different layer than the underlayer. In such an embodiment, both the underlayer and the responsive layer may be tuned to perform optimally for their specific purpose.

In an embodiment, responsive layers disclosed herein may comprise many different material systems. Generally, the material systems for the responsive layer comprise materials that can undergo a reflow in response to a treatment stimulus. In some embodiments, the responsive layer may be an organic material. For example, the responsive layer may comprise one or more of polymethyl methacrylate (PMMA), polystyrene (PS), Nylon 12, or polydimethylglutarimide (PMGI), parylene, or the like. More generally, responsive layers may comprise linear polymers with reflow behavior or polymer networks with reversible chemistry (e.g., reversible crosslinking or supramolecular crosslinking). In other embodiments, the responsive layer may be an inorganic material. For example, the responsive layer may comprise one or more of tin, bismuth, indium, or selenium. More generally, inorganic materials may be materials with reflow behavior at low temperatures (e.g., low melting temperatures). Other embodiments comprise polymers with disulfide bonds. For example, a polyurethane with disulfide bonds may be used in some embodiments.

In an embodiment, the responsive layers may be deposited with various different deposition processes. For example, dry deposition processes, such as chemical vapor deposition (CVD), plasma enhanced CVD (PE-CVD), atomic layer deposition (ALD), plasma enhanced ALD (PE-ALD), physical vapor deposition (PVD), or the like may be used in some embodiments. Dry processes may also comprise molecular layer deposition (MLD) processes. In an embodiment, wet processes, such as spin-coating, may be used in order to deposit the responsive layer.

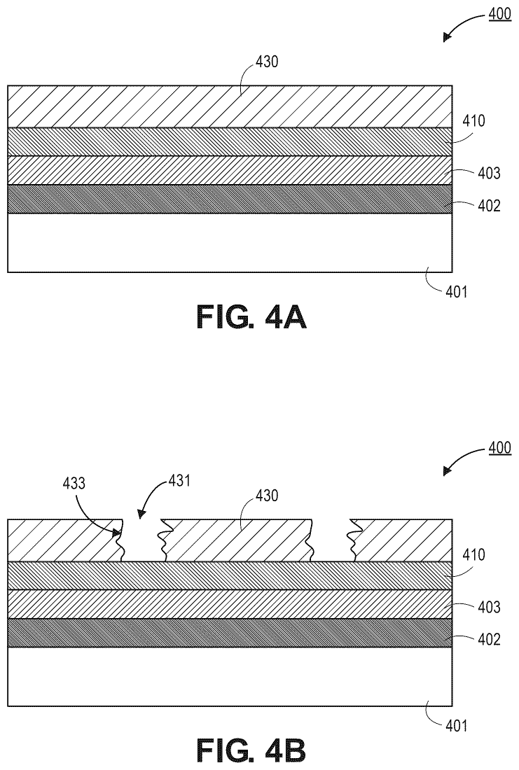

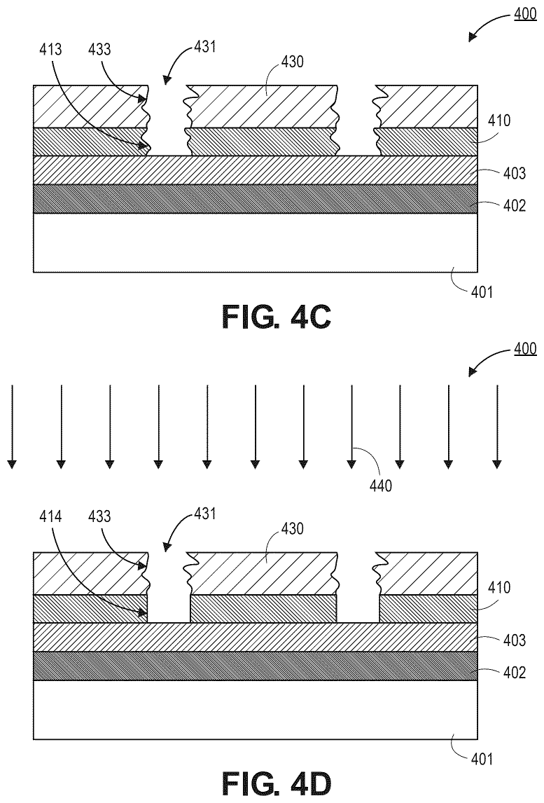

Referring now to FIG. 3A, a cross-sectional illustration of a device 300 is shown, in accordance with an embodiment. In an embodiment, the device 300 may comprise a substrate 301. The substrate 301 may be a semiconductor substrate, such as a silicon wafer. Though, other semiconductor materials, ceramics, glasses, or the like may also be used for the substrate 301. The substrate 301 may also have a form factor other than a form factor of a wafer.

In an embodiment, a patterning stack is provided over the substrate 301. In an embodiment, the patterning stack may comprise a carbon containing layer 302. The carbon containing layer 302 may be a spin-on-carbon (SOC) material. In an embodiment, a hardmask 303 may be provided over the carbon containing layer 302. In an embodiment, the hardmask 303 may comprise any suitable material, such as an organic hardmask, an inorganic hardmask, or the like. For example, the hardmask 303 may comprise silicon, nitrogen, metallic elements, oxygen, carbon, or any other suitable element for hardmask 303 development.

In an embodiment, a responsive layer 310 is provided over the hardmask 303. The responsive layer 310 may be a material that is capable of being reflown in response to a stimulus. For example, the stimulus may comprise a thermal stimulus, an electromagnetic radiation stimulus (e.g., light, UV light, etc.), or a chemical stimulus. As will be described in greater detail below, the responsive layer 310 may be patterned. The responsive layer 310 is then treated with the stimulus in order to reduce a LER and/or LWR of the patterned surfaces of the responsive layer 310.

In an embodiment, the responsive layer 310 may comprise an organic material. For example, the responsive layer 310 may comprise linear polymers with reflow behavior, or polymer networks with reversible chemistry (e.g., reversible crosslinking or supramolecular crosslinking). For example, the responsive layer 310 may comprise one or more of PMMA, PS, Nylon 12, or PMGI. Such polymeric materials may be deposited with a spin-on process, CVD processes, or ALD processes. Though, other deposition processes may also be used in some embodiments.

In another embodiment, the responsive layer 310 may comprise an inorganic material. For example, the responsive layer 310 may comprise one or more of tin, bismuth, indium, or selenium. More generally, inorganic materials may be materials with reflow behavior at low temperatures (e.g., low melting temperatures). Inorganic materials may be deposited with PVD processes, CVD processes or ALD processes. Though, other deposition processes may also be used in some embodiments.

Other embodiments comprise a responsive layer 310 that comprise polymers with disulfide bonds. For example, a polyurethane with disulfide bonds may be used in some embodiments. The use of disulfide bonds allows for the responsive layer 310 to reflow in a controllable manner in response to a given stimulus (e.g., heat or light). Such disulfide based polymers may be deposited with an MLD process. Though, other deposition processes may also be used in some embodiments.

In some embodiments, the reflow of the responsive layer is implemented at a low temperature that is compatible with the rest of the patterning stack. For example, the resist layer 330 is often damaged (e.g., melts or reflows) at low temperatures. As such, reflow temperatures may be provided up to approximately 250° C. in some instances. Stimulus options other than heat (e.g., chemical and light) can also be used in order to protect the rest of the patterning stack from elevated temperatures.

In the embodiment shown in FIG. 3A, the responsive layer 310 may also function as an underlayer. That is, the responsive layer 310 may play an active role in the chemical transformation of the exposed regions of the resist layer 330 during the lithographic exposure. For example, the responsive layer 310 may be a source of secondary electrons and/or chemical species or radicals that diffuse into the resist layer 330. These electrons and species can improve the rate of chemical reaction within the resist layer 330 in order to lower the necessary dose, improve contrast, and/or otherwise improve patterning performance.

In an embodiment, the resist layer 330 is provided over the responsive layer 310. The resist layer 330 may be any suitable photosensitive material that is compatible with a given lithography process. An EUV resist layer 330 is described in detail herein. However, it is to be appreciated that the resist layer 330 may also be a deep ultraviolet (DUV) resist layer 330, or a resist layer 330 compatible with any other wavelength or wavelengths of electromagnetic radiation. In a particular embodiment, the resist layer 330 may comprise a metal-oxide material composition. For example, the resist layer 330 may comprise a tin-oxide material system. In other embodiments, the resist layer 330 may comprise a CAR material system.

The resist layer 330 may be deposited over the responsive layer 310 with any suitable process. In one embodiment, the resist layer 330 is deposited with a spin-on process. In other embodiments, the resist layer 330 is deposited with a dry deposition process, such as a CVD process, a PE-CVD process, an ALD process, a PE-ALD process, or the like. In a dry deposition process, the composition of the resist layer 330 may be varied through a thickness of the resist layer 330. For example, a bottom of the resist layer 330 may be tuned for adhesion, and the rest of the resist layer 330 may be tuned for sensitivity to EUV radiation.

Referring now to FIG. 3B, a cross-sectional illustration of a device 300 is shown, in accordance with an additional embodiment. In an embodiment, the device 300 in FIG. 3B may be similar to the device 300 in FIG. 3A, with the addition of an underlayer 315. The underlayer 315 may be provided between the responsive layer 310 and the resist layer 330. The underlayer 315 may comprise any suitable underlayer material composition. For example, the underlayer 315 may comprise one or more of silicon, carbon, oxygen, or hydrogen. Other elements may also be integrated into the underlayer 315 in different embodiments. The underlayer 315 may be tuned to improve the patterning performance of the resist layer 330. For example, a chemical structure of the underlayer 315 may generate more secondary electrons, radicals, and/or other chemical species that can diffuse into the resist layer 330 during EUV exposure. Separating the underlayer 315 from the responsive layer 310 allows for improved optimization of both layers. Since the responsive layer 310 no longer needs to participate in the exposure process, the responsive layer 310 can be designed for improved reflow performance. Improved reflow performance may include the ability to reflow with a smaller stimulus (e.g., lower temperatures, lower light flux, smaller concentration of chemistries, etc.), and/or greater reductions in LER and/or LWR.

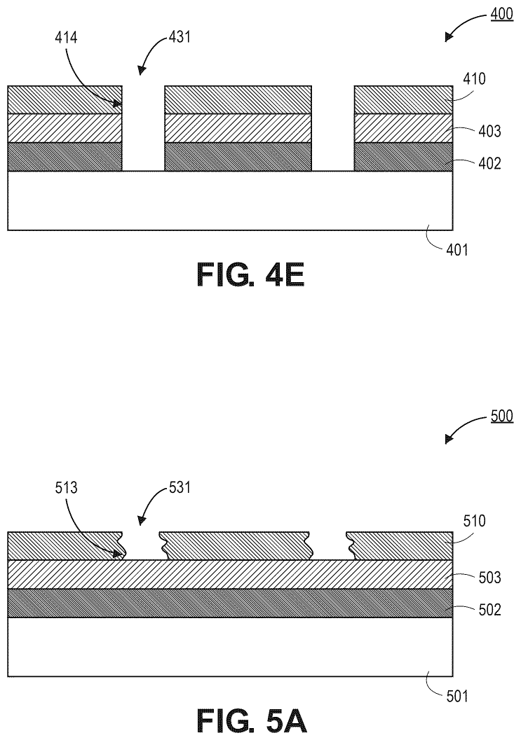

Referring now to FIGS. 4A-4E, a series of cross-sectional illustrations depicting a process for patterning a patterning stack with improved LER and/or LWR is shown, in accordance with an embodiment. In an embodiment, the device 400 in FIGS. 4A-4E has a patterning stack that is similar to the patterning stack of device 300 in FIG. 3A. Though, it is to be appreciated that patterning stacks similar to any of those described in greater detail herein may be patterned with similar processes in accordance with various embodiments.

Referring now to FIG. 4A, a cross-sectional illustration of a device 400 is shown, in accordance with an embodiment. In an embodiment, the device 400 may comprise a substrate 401. The substrate 401 may be similar to the substrate 301 described in greater detail above. Similarly, carbon containing layer 402 and hardmask 403 may be similar to the carbon containing layer 302 and the hardmask 303 described in greater detail above.

In an embodiment, a responsive layer 410 is provided over the hardmask 403. The responsive layer 410 may be similar to any of the responsive layers described in greater detail herein. For example, the responsive layer 410 may be a material that is responsive to a stimulus. That is, the application of a stimulus (e.g., heat, light, chemicals) may result in the responsive layer 410 reflowing in order to reduce a LER and/or a LWR. Generally, the responsive layer 410 may be an organic material, an inorganic material, or a disulfide based material. The responsive layer 410 may be deposited over the hardmask 403 with a spin-coating process or a dry deposition process (e.g., CVD, PE-CVD, ALD, PE-ALD, PVD, MLD, etc.).

In an embodiment a resist layer 430 is provided over the responsive layer 410. The resist layer 430 may comprise an EUV resist material or the like. For example, the resist layer 430 may comprise a metal-oxide resist or a CAR. The resist layer 430 may be applied with a dry deposition process or a spin-coating process. The resist layer 430 may be similar to any of the resist layers described in greater detail herein.

Referring now to FIG. 4B, a cross-sectional illustration of the device 400 after an exposure and developing process has been performed is shown, in accordance with an embodiment. In an embodiment, the resist layer 430 is selectively exposed with EUV radiation (or other suitable electromagnetic radiation) through the use of a mask and/or reticle (not shown). The EUV radiation initiates a chemical reaction within the resist layer 430. The chemical reaction may result in a solubility change of the exposed regions of the resist layer 430 in order to form a latent image of the desired pattern.

After exposure, a developing process (e.g., an etching process) may be used to selectively remove the exposed regions relative to the unexposed regions, or the unexposed regions may be selectively removed relative to the exposed regions (depending on if the resist is a positive tone resist or a negative tone resist). As shown, the developing process may result in the formation of openings 431 through the resist layer 430. The openings 431 may be holes, trenches, or any other desired pattern that passes through a thickness of the resist layer 430.

In an embodiment, the openings 431 may have sidewalls 433. As illustrated, the sidewalls 433 may have a relatively high LER and LWR. This may be due (at least in part) to the use of a low dosage exposure for the resist layer 430. For example, the dosage of the exposure may be approximately 30 mJ/cm² or lower, or approximately 15 mJ/cm² or lower. Though, any dose may benefit from embodiments disclosed herein.

Referring now to FIG. 4C, a cross-sectional illustration of the device 400 after the pattern of the openings 431 is transferred into the underlying responsive layer 410 is shown, in accordance with an embodiment. In an embodiment, the pattern may be transferred with an etching process. The etching process may be a wet etch or a dry etch. As shown, the openings 431 continue into the responsive layer 410 and include sidewalls 413. Similar to the sidewalls 433, the sidewalls 413 may comprise a high LER and LWR. This is due to the pattern transfer from the resist layer 430 to the responsive layer 410. In an embodiment, the etching process used to transfer the pattern 431 into the responsive layer 410 may comprise an O₂ and CH₄ plasma. In other embodiments, the etching process may comprise O₂ only. In such an embodiment that use O₂ only, changes to CD may be minimized. This can be particularly beneficial when used with patterns 431 that have a tighter pitch.

Referring now to FIG. 4D, a cross-sectional illustration of the device after a stimulus treatment process is shown, in accordance with an embodiment. As shown a stimulus 440 is applied to the device 400. The stimulus 440 initiates a reflow of the responsive layer 410. While in a reflow state, the responsive layer 410 is able to adjust free surfaces (e.g., sidewalls 414) in order to minimize surface energy. Accordingly, the high LER and LWR of the sidewall 413 in FIG. 4C is reduced in FIG. 4D. The improved LER and LWR of the of the sidewall 414 in the modified responsive layer 410 can be used in order to provide improved patterning in the underlying layers without needing higher exposure dosages. This reduces costs and improves throughput without sacrificing performance.

The stimulus 440 may comprise a thermal stimulus. For example, the stimulus 440 may be applied by thermal lamps in an annealing chamber or the like. A hot-plate, a heated pedestal, a heated electrostatic chuck (ESC), or the like may also be used to apply thermal energy to the device 400. A laser may also apply the necessary thermal energy in some embodiments. The thermal energy may allow for the responsive layer 410 to reflow due to the material exceeding a glass transition temperature or a melting temperature.

In the case of a rapid thermal anneal, such as a laser annealing reflow, rapid heating of the responsive layer 410 is provided. For example, the laser may have a wavelength that substantially passes through the layers above the substrate 401 in order to heat the substrate 401. For example, the wavelength of the laser may be 810 nm in some embodiments. In an embodiment, the laser annealing may raise a temperature of the responsive layer 410 to a temperature above approximately 190° C. In some instances, the etching chemistry used to transfer the pattern into the responsive layer may impact the laser annealing condition. For example, when an O₂ and CH₄ chemistry is used, a lower temperature (e.g., around 230° C.) may provide improvement, and when an O₂ chemistry is used by itself a higher temperature may be necessary to observe improvements (e.g., above 230° C.). A dwell time of the laser annealing may be between approximately 1,000 us and approximately 4,000 μs. Though, longer dwell times or shorter dwell times may also be used in some embodiments.

The rapid heating provides the necessary energy to allow for reflow of the sidewall 414 of the responsive layer 410 in order to minimize LER and/or LWR. Further, the use of laser annealing provides rapid cooling after the reflow of the surface of the sidewall 414. This prevents the bulk of the responsive layer 410 from reflowing, which may otherwise result in the merging of patterned features, as may be the case if the substrate 401 were heated on a heat plate or in a heated chamber.

The stimulus 440 may also comprise an electromagnetic radiation exposure (e.g., UV radiation, visible light, etc.). Such a stimulus 440 may be more controllable than other solutions. For example, a light source may be provided over the device 400, and the light source can provide a desired dose of the light in order to obtain the desired effect. Light exposure may allow for reflow through an increase in the flowability of the material, change in a chemical structure (e.g., reversible cross-linking, supramolecular cross-linking, etc.).

The stimulus 440 may also comprise a chemical stimulus 440. A chemical stimulus 440 may be applied through the injection of a chemical reagent into a chamber that triggers a reflow behavior. For example, chambers suitable for CVD or ALD processes may be used in order to apply the chemical reagents of the stimulus 440 to the responsive layer 410.

The stimulus 440 may also comprise ion implantation. In an embodiment, ions with a relatively high molecular weight (e.g., xenon, argon, etc.) or any other suitable ion (e.g., neon, helium, nitrogen (N₂)) may be implanted into the sidewalls 414 of the responsive layer 410. The implant angle may be any suitable angle that can reach the sidewalls 414. For example, the implant angle may be between approximately 10° and approximately 90°. Implantation energies may range from approximately 0.1 MeV to approximately 1.0 MeV.

The higher molecular weight may limit the penetration depth of the implanted ion into the responsive layer 410. Accordingly, a high amount of energy is locally provided to the sidewall 414 of the responsive layer 410 in order to enable localized surface reflow. For example, ion temperatures may reach 104K, while providing a rapid temperature decay back to the substrate 401 temperature in approximately 10⁻⁹ s. The implantation may also result in random scission of polymer chains and carbon backbone fragmentation and condensation through cyclization and/or aromatization. As such, sufficient reflow of the sidewalls 414 to minimize LER and/or LWR is provided. In some instances, the resulting surface of the sidewall 414 may include a dense carbon-rich surface layer after the implantation.

Referring now to FIG. 4E, a cross-sectional illustration of the device 400 after the resist layer 430 is stripped is shown, in accordance with an embodiment. In an embodiment, stripping the resist layer 430 may include a plasma based process. For example, an HBr plasma, an O₂ plasma, a CO plasma, or any combination thereof may be used in some embodiments. The use of HBr and/or O₂ plasmas may be used to further improve LER and/or LWR of the pattern 431. For example, the plasma constituents may lead to surface relaxation through chain scission that lowers the glass transition temperature of the sidewall 414 of the responsive layer 410.

After the resist layer 430 is stripped, the responsive layer 410 is now the uppermost layer, and sets the pattern for the openings 431. Due to the low LER and LWR of the sidewalls 414, subsequent pattern transfer into the hardmask 403 and the carbon containing layer 402 will also result in low LER and LWR features. The pattern of the openings 431 may be passed into the hardmask 403 and the carbon containing layer 402 with any suitable etching process. After the patterning stack is fully patterned, an etching process may be used to pattern the underlying substrate 401. The etching of the substrate 401 may include a dry etching process, a wet etching process, or the like.

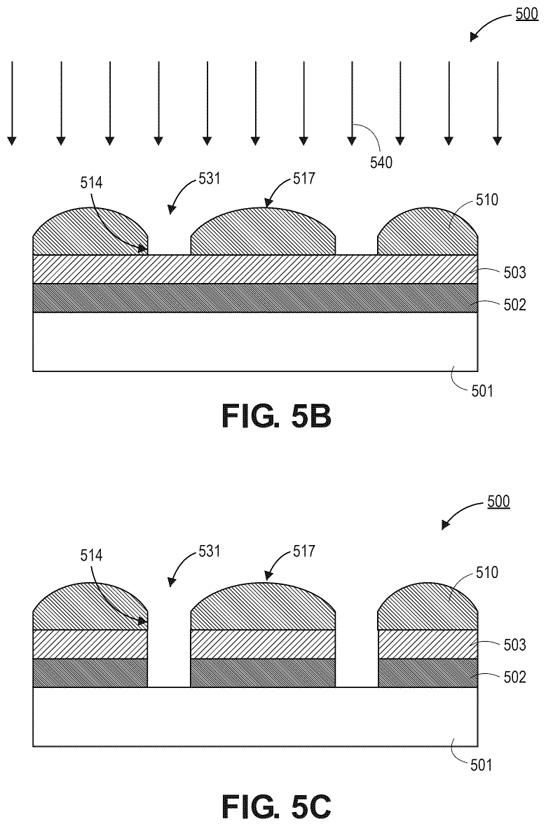

Referring now to FIGS. 5A-5C, a series of cross-sectional illustrations depicting a process for reflowing a responsive layer 510 to reduce LER and LWR is shown, in accordance with an embodiment. In an embodiment, the process depicted in FIGS. 5A-5C may be similar to the process depicted in FIGS. 4A-4E with the exception of when the resist layer is stripped.

Referring now to FIG. 5A, a cross-sectional illustration of a device 500 is shown, in accordance with an embodiment. In an embodiment, the device 500 may comprise a substrate 501. The substrate 501 may be similar to the substrate 301 described in greater detail above. Similarly, carbon containing layer 502 and hardmask 503 may be similar to the carbon containing layer 302 and the hardmask 303 described in greater detail above.

In an embodiment, a responsive layer 510 is provided over the hardmask 503. The responsive layer 510 may be similar to any of the responsive layers described in greater detail herein. For example, the responsive layer 510 may be a material that is responsive to a stimulus. That is, the application of a stimulus (e.g., heat, light, chemicals) may result in the responsive layer 510 reflowing in order to reduce a LER and/or a LWR. Generally, the responsive layer 510 may be an organic material, an inorganic material, or a disulfide based material. The responsive layer 510 may be deposited over the hardmask 503 with a spin-coating process or a dry deposition process (e.g., CVD, PE-CVD, ALD, PE-ALD, PVD, MLD, etc.).

As shown in FIG. 5A, the responsive layer 510 has been patterned to form openings 531. The patterning process to form the openings 531 may be similar to the processing operations described above with respect to FIGS. 4A-4C. As shown, the openings 531 may have sidewalls 513 that have high LER and LWR. This is due to the overlying resist layer (not shown in FIG. 5A) being exposed with a low dose so that the resist layer has high LER and LWR sidewalls. However, instead of leaving the resist layer over the patterned responsive layer 510 during stimulus treatment, the resist layer is stripped. In an embodiment, stripping the resist layer may include a plasma based process. For example, an HBr plasma, an O₂ plasma, a CO plasma, or any combination thereof may be used in some embodiments. The use of HBr, CO, and/or O₂ plasmas may be used to further improve LER and/or LWR of the pattern 531. For example, the plasma constituents may lead to surface relaxation through random chain scission that modifies the physical properties of the polymer such as depressing the melting temperature and glass transition temperature of the sidewall 513 of the responsive layer 510. Stripping the resist layer may allow for the stimulus to have easier access to the responsive layer 510.

Referring now to FIG. 5B, a cross-sectional illustration of the device 500 during a stimulus 540 treatment is shown, in accordance with an embodiment. As shown a stimulus 540 is applied to the device 500. The stimulus 540 initiates a reflow of the responsive layer 510. While in a reflow state, the responsive layer 510 is able to adjust free surfaces (e.g., sidewalls 514 and top surface 517) in order to minimize surface energy. Accordingly, the high LER and LWR of the sidewall 513 in FIG. 5A is reduced in FIG. 5B. The improved LER and LWR of the of the sidewall 514 of the modified responsive layer 510 can be used in order to provide improved patterning in the underlying layers without needing higher exposure dosages. This reduces costs and improves throughput without sacrificing performance. Further, since there is no structure over the top surface 517 of the responsive layer 510, a curved surface may be generated in order to reduce surface energy.

The stimulus 540 may comprise a thermal stimulus 540. For example, the stimulus 540 may be applied by thermal lamps in an annealing chamber or the like. A hot-plate, a heated pedestal, a heated ESC, or the like may also be used to apply thermal energy to the device 500. A laser may also apply the necessary thermal energy in some embodiments. The thermal energy may allow for the responsive layer 510 to reflow due to the material exceeding a glass transition temperature or a melting temperature.

In the case of a laser annealing reflow, rapid heating of the responsive layer 510 is provided. For example, the laser may have a wavelength that substantially passes through the layers above the substrate 501 in order to heat the substrate 501. For example, the wavelength of the laser may be 810 nm in some embodiments. In an embodiment, the laser annealing may raise a temperature of the responsive layer 510 to a temperature above approximately 190° C. A dwell time of the laser annealing may be up to 1,000 us or up to 2,000 μs. Though, longer dwell times may also be used in some embodiments.

The rapid heating provides the necessary energy to allow for reflow of the sidewall 513 of the responsive layer 510 in order to minimize LER and/or LWR. Further, the use of laser annealing provides rapid cooling after the reflow of the surface of the sidewall 513. This prevents the bulk of the responsive layer 510 from reflowing, which may otherwise result in the merging of patterned features, as may be the case if the substrate 501 were heated on a heat plate or in a heated chamber.

The stimulus 540 may also comprise an electromagnetic radiation exposure (e.g., UV radiation, visible light, etc.). Such a stimulus 540 may be more controllable than other solutions. For example, a light source may be provided over the device 500, and the light source can provide a desired dose of the light in order to obtain the desired effect. Light exposure may allow for reflow through an increase in the flowability of the material, change in a chemical structure (e.g., reversible cross-linking, supramolecular cross-linking, etc.).

The stimulus 540 may also comprise a chemical stimulus 540. A chemical stimulus 540 may be applied through the injection of a chemical reagent into a chamber that triggers a reflow behavior. For example, chambers suitable for CVD or ALD processes may be used in order to apply the chemical reagents of the stimulus 540 to the responsive layer 510.

The stimulus 540 may also comprise ion implantation. In an embodiment, ions with a relatively high molecular weight (e.g., xenon, argon, etc.) or any other suitable ion (e.g., neon, helium, nitrogen (N₂)) may be implanted into the sidewalls 513 of the responsive layer 510. The implant angle may be any suitable angle that can reach the sidewalls 513. For example, the implant angle may be between approximately 10° and approximately 90°. Implantation energies may range from approximately 0.1 MeV to approximately 1.0 MeV.

The higher molecular weight may limit the penetration depth of the implanted ion into the responsive layer 510. Accordingly, a high amount of energy is locally provided to the sidewall 513 of the responsive layer 510 in order to provide localized surface reflow. For example, ion temperatures may reach 104K, while providing a rapid temperature decay to the substrate 501 temperature in approximately 10⁻⁹ s. The implantation may also result in random scission of polymer chains and carbon backbone fragmentation and condensation through cyclization and/or aromatization. As such, sufficient reflow of the sidewalls 513 to minimize LER and/or LWR is provided. In some instances, the resulting surface of the sidewall 513 may include a dense carbon-rich surface layer after the implantation.

Referring now to FIG. 5C, a cross-sectional illustration of the device 500 after the pattern is transferred into the remainder of the patterning stack is shown, in accordance with an embodiment. Due to the low LER and LWR of the sidewalls 514, subsequent pattern transfer into the hardmask 503 and the carbon containing layer 502 will also result in low LER and LWR features. The pattern of the openings 531 may be passed into the hardmask 503 and the carbon containing layer 502 with any suitable etching process. After the patterning stack is fully patterned, an etching process may be used to pattern the underlying substrate 501. The etching of the substrate 501 may include a dry etching process, a wet etching process, or the like.

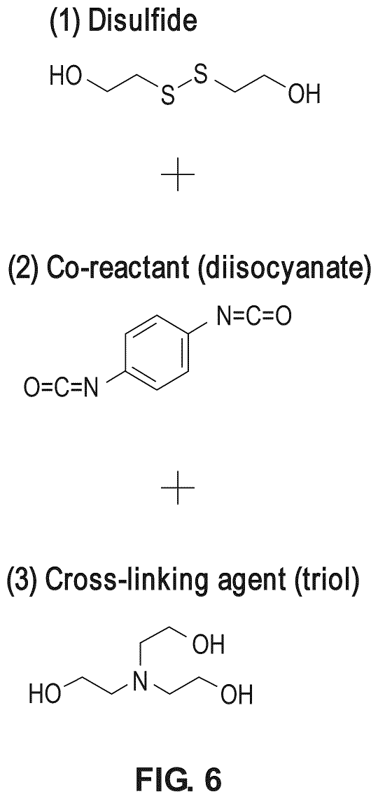

Referring now to FIG. 6, a chemical diagram of the formation of a material comprising disulfide bonds is shown, in accordance with an embodiment. As shown, a disulfide (1) is added to a co-reactant (2) and a cross-linking agent (3). In an embodiment, the co-reactant may comprise a diisocyanate and the cross-linking agent may comprise a triol. Though, it is to be appreciated that other chemical structures that allow for suitable disulfide bonds that enable reflow may be used in accordance with embodiments described herein. In some embodiments, the disulfide structure may be integrated into an organic polymer, such as a polyurethane or the like. In an embodiment, disulfide bond materials may be deposited with an MLD process, a CVD process, an ALD process, or the like.

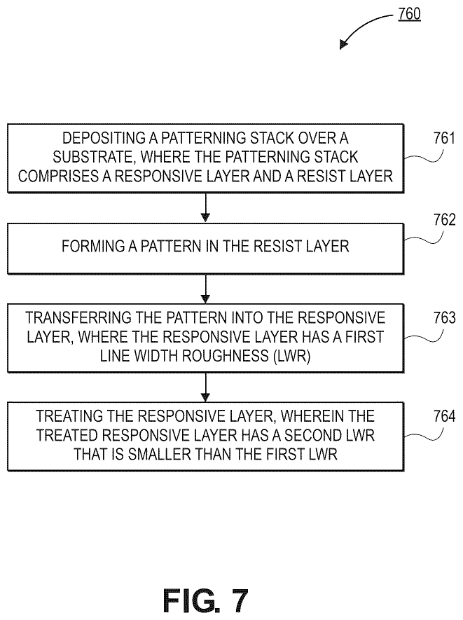

Referring now to FIG. 7, a process flow diagram of a process 760 for improving LER and/or LWR in a patterning stack is shown, in accordance with an embodiment. In an embodiment, the process 760 may begin with operation 761, which comprises depositing a patterning stack over a substrate. In an embodiment, the patterning stack comprises a responsive layer and a resist layer. For example, the patterning stack may be similar to any of the patterning stacks described in greater detail herein. The responsive layer may be a material that is capable of reflowing upon treatment with a stimulus, such as a thermal stimulus, a light stimulus, or a chemical stimulus. The responsive layer may be similar to any of the responsive layers described in greater detail herein. The resist layer may also be similar to any of the resist layers described in greater detail herein. For example, the resist layer may be an EUV resist material.

In an embodiment, the process may continue with operation 762, which comprises forming a pattern in the resist layer. The pattern in the resist layer may be formed by exposing the resist layer with electromagnetic radiation that drives a chemical reaction in the resist layer. In an embodiment, the exposure may be considered a relatively low dose exposure. For example, an exposure dose may be approximately 30 mJ/cm² or lower, or approximately 15 mJ/cm² or lower. Though, any dose may benefit from embodiments disclosed herein. After a latent image is formed in the resist layer, a developing process may form openings, trenches, or the like through the resist layer.

In an embodiment, the process may continue with operation 763, which comprises transferring the pattern into the responsive layer. In an embodiment, the responsive layer has a first LWR and/or a first LER. The first LWR and the first LER may be relatively high, due to the low dose of the resist layer exposure.

In an embodiment, the process may continue with operation 764, which comprises treating the responsive layer. In an embodiment, the treated responsive layer has a second LWR and/or a second LER that is smaller than the first LWR and/or the first LER. The treatment may be the application of a stimulus (e.g., a thermal stimulus, a light based stimulus, or a chemical stimulus) that causes the responsive layer to reflow. The reflowing responsive layer rearranges the surface profile in order to minimize a surface energy of the responsive layer. This results in a more linear surface with a smaller LWR and LER. In an embodiment, the treatment may also comprise a laser annealing treatment, an ion implantation treatment, and/or a plasma treatment, such as those described in greater detail herein.

After the responsive layer is reflown to reduce LWR and LER, the pattern in the responsive layer can be transferred into the rest of the patterning stack. The underlying substrate can then be patterned with a suitable etching process. In this manner, highly accurate, precise, and repeatable patterning can be provided on a device using EUV lithography with low exposure dosages. This reduces the cost of the lithography process and improves throughput.

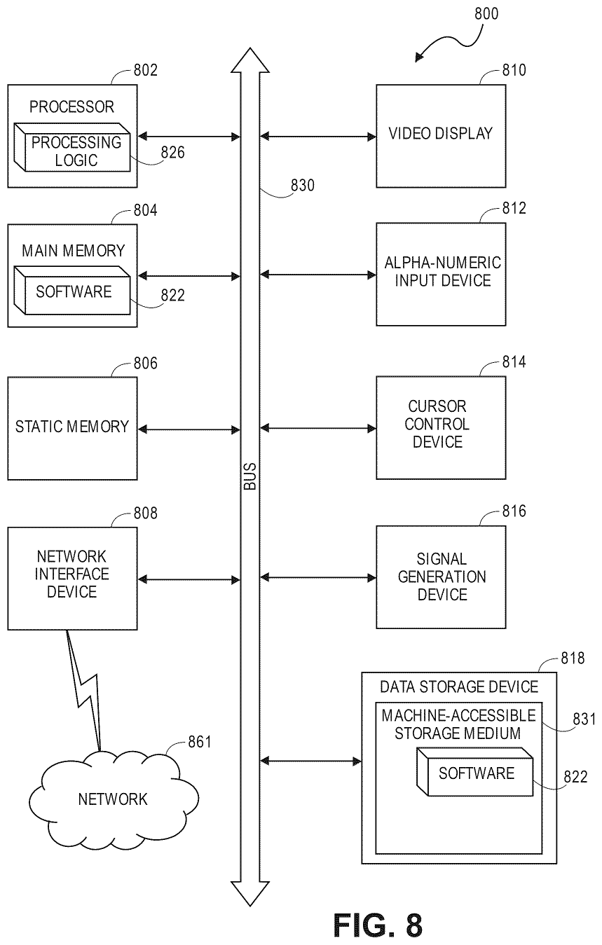

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for lithographic patterning, comprising:
depositing a patterning stack over a substrate, wherein the patterning stack comprises a responsive layer and a resist layer;
forming a pattern in the resist layer;
transferring the pattern into the responsive layer, wherein the responsive layer has a first line width roughness (LWR); and
treating the responsive layer, wherein the treated responsive layer has a second LWR that is smaller than the first LWR.

2. The method of claim 1, wherein the responsive layer is treated with a rapid thermal annealing process.

3. The method of claim 2, wherein the rapid thermal annealing process is carried out with laser annealing comprising a dwell time up to 4,000 μs.

4. The method of claim 1, wherein the responsive layer is treated with an ion implantation process.

5. The method of claim 4, wherein the ion implantation process uses xenon, neon, helium, nitrogen, and/or argon ions, and wherein the ions are delivered at an angle between 10° and 90°.

6. The method of claim 1, wherein the responsive layer is patterned and/or treated with a plasma treatment process.

7. The method of claim 6, wherein the plasma treatment process comprises an HBr plasma, a CH₄ plasma, an O₂ plasma, a CO plasma, or any combination thereof.

8. The method of claim 1, wherein the responsive layer comprises an organic polymer or an inorganic material.

9. The method of claim 1, wherein the resist layer is stripped before or after treating the responsive layer.

10. The method of claim 1, wherein the responsive layer comprises a disulfide material.

11. The method of claim 1, wherein the responsive layer is deposited with a chemical vapor deposition (CVD) process, an atomic layer deposition (ALD) process, or a molecular deposition (MLD) process.

12. The method of claim 1, wherein the resist layer comprises an extreme ultraviolet (EUV) resist with a metal-oxide material system, a chemically amplified resist (CAR) material system, or any other EUV patternable material.

13. A method for lithographic patterning, comprising:
depositing a patterning stack on a substrate, wherein the patterning stack comprises:
a carbon layer;
a hardmask layer;
a responsive layer; and
a resist layer over the responsive layer;
forming a pattern in the resist layer;
transferring the pattern into the responsive layer; and
reflowing the responsive layer through application of a stimulus, wherein a line edge roughness (LER) of the responsive layer is reduced by the reflowing.

14. The method of claim 13, wherein the stimulus comprises one or more of a rapid thermal anneal, ion implantation, or a plasma treatment.

15. The method of claim 13, wherein the responsive layer comprises one or more of polymethyl methacrylate (PMMA), polystyrene (PS), Nylon 12, polydimethylglutarimide (PMGI), or parylene.

16. The method of claim 13, wherein the responsive layer comprises one or more of tin, bismuth, indium, or selenium.

17. The method of claim 13, wherein the responsive layer comprises a disulfide material.

18. A lithography patterning stack, comprising:
a carbon containing layer;
a hardmask layer over the carbon containing layer;
a responsive layer over the hardmask layer, wherein the responsive layer comprises a material that is configured to reflow in the presence of a stimulus that includes one or more of a rapid thermal anneal, ion implantation, or a plasma treatment; and
a resist layer over the responsive layer.

19. The lithography patterning stack of claim 18, further comprising:
an underlayer between the responsive layer and the resist layer.

20. The lithography patterning stack of claim 18, wherein the resist layer is an extreme ultraviolet (EUV) resist.
